(19) United States
(12) Patent Application Publication
(10) Pub. No.: US 2016/0293875 A1
(43) Pub. Date: Oct. 6, 2016

(54) METHOD FOR MANUFACTURING QUANTUM DOT LIGHT-EMITTING ELEMENT AND DISPLAY DEVICE USING QUANTUM DOT

(71) Applicant: BOE TECHNOLOGY GROUP CO., LTD., BEIJING (CN)

(72) Inventors: Feng ZHANG, (US); Qi YAO, BEIJING (CN)

(73) Assignee: BOE TECHNNOLOGY GROUP CO., LTD., BEIJING (CN)

(21) Appl. No.: 14/369,653

(22) PCT Filed: Dec. 4, 2013
(86) PCT No.: PCT/CH2013/088532

§ 371 Date: Jun. 27, 2014

(30) Foreign Application Priority Data
Aug. 21, 2013 (CN) 201310367430.2

(51) Int. Cl. H01L 51/50; H01L 51/56; H01L 51/52; H01L 27/32

(52) U.S. Cl. CPC H01L 51/502; H01L 27/322; H01L 51/56; H01L 51/5056; H01L 51/5072; H01L 51/5284; H01L 27/3246; H01L 2227/323

(57) ABSTRACT

The present invention provides a method for manufacturing a quantum dot light-emitting element and a display device. The method comprises mixing a quantum dot light-emitting material and a hole-transporting material or mixing the quantum dot light-emitting material and an electron-transporting material, and dissolving a mixture into an organic solvent to form a mixed solvent, applying the mixed solvent to a substrate for manufacturing a quantum dot light-emitting element, removing the organic solvent form the mixed solvent to stratify the quantum dot light-emitting material and the hole-transporting material or the electron-transporting material on the substrate for manufacturing a quantum dot light-emitting element to form a quantum dot light-emitting layer and a hole-transporting layer or an electron-transporting layer.

### CROSS-REFERENCE TO RELATED APPLICATION

This application is the U.S. national phase of PCT Application No. PCT/CN2013/088532 filed on Dec. 4, 2013, which claims priority to Chinese Patent Application No. 201310367430.2 filed on Aug. 21, 2013, the disclosures of which are incorporated in their entirety by reference herein.

### TECHNICAL FIELD

The present invention relates to a field of display technology, and in particular to a method for manufacturing a quantum dot light-emitting element and a display device using a quantum dot.

### BACKGROUND

A quantum dot (QD) is a nano-crystal as well and is a quasi-zero-dimensional nano-material. All sizes of the quantum dot in three dimensions are between 1 nm and 10 nm, and movements of an electron inside the quantum dot in all directions are confined, so quantum confinement effect is especially serious. Because the electron and a hole are confined by a quantum, a continuous energy band structure becomes a discrete energy level structure having molecular character. Regarding to the quantum dots having different sizes, degrees of confinement of the electron and the hole by the quantum are different, the discrete energy level structure having the molecular character varies with the size of the quantum dot. Therefore, after excitation by external energy, the different sizes of quantum dots will emit fluorescence having different wave lengths, namely a variety of colors light. Additionally, wave length of the light emitted by a quantum dot is only relate to an energy level structure of the quantum dot (the size of the quantum dot), so a full width at half maximum (FWHM) is narrow, and a purity of the emitted light is high. A display device using a quantum dot light-emitting material has abroad color gamut and a good display quality.

Comparing with a traditional organic light-emitting diode (OLED) which uses an organic light-emitting material, a quantum dot light-emitting diode (QLED) uses a quantum dot light-emitting material instead of the organic light-emitting material to form a light-emitting layer. A display device using the QLED can implement three primary colors, namely R, G and B, and a white light by controlling the size of the quantum dot, and the display device using the QLED has a broad color gamut and high display brightness. Additionally, the display device using the QLED can be manufactured by using an existing process production line for the OLED and other flat display devices. In view of the description above, people pay more and more attention on the display device using the QLED, and the display device using the QLED may become the next generation of display device.

As shown in FIG. 1, the quantum dot light-emitting element generally comprises: an anode 10 and a cathode 50 provided between a lower substrate 100 and an upper substrate 200 which are opposite to each other, and a quantum light-emitting layer 30 having multiple quantum dots 31 which is formed between the anode 10 and the cathode 50, wherein a hole-transporting layer 20 formed from hole-transporting particles is formed on the anode 10, and the quantum light-emitting layer 30 is formed on the hole-transporting layer 20. An electron-transporting layer 40 formed from electron-transporting particles and the cathode 50 are formed on the quantum light-emitting layer 30 in turn.

In a method for manufacturing the quantum dot light-emitting element according to the prior art, each layer of the quantum dot light-emitting element is formed in way of a step-by-step preparation or layer-by-layer preparation, and generally the quantum dot light-emitting layer is formed on the hole-transporting layer by a solution process. When the quantum dot light-emitting layer is formed, components of the hole-transporting layer may be dissolved by a solvent used for forming the quantum dot light-emitting layer, and the components of the hole-transporting layer below the quantum dot light-emitting layer may also be dissolved, it is required to select a material which cannot be dissolved in the solution. Therefore, the material for preparing the hole-transporting layer is limited. Additionally, when adopting the above method, preparation for the quantum dot light-emitting element has more procedures and is complex. Therefore, it is difficult to reduce manufacturing cost.

### SUMMARY

A purpose of the technical scheme of the present invention is to provide a method for manufacturing a quantum dot light-emitting element, which is used to simply a procedure for manufacturing the current quantum dot light-emitting element and reduce manufacturing cost of the quantum dot light-emitting element, and a display device using quantum dot.

The present invention provides a method for manufacturing a quantum dot light-emitting element, which comprises:

mixing a quantum dot light-emitting material and a hole-transporting material and dissolving a mixture into an organic solvent to form a first mixed solvent,

applying the first mixed solvent to a first substrate for manufacturing the quantum dot light-emitting element,

removing the organic solvent in the first mixed solvent to stratify the quantum dot light-emitting material and the hole-transporting material on the substrate and to form a quantum dot light-emitting layer and a hole-transporting layer,

or

mixing the quantum dot light-emitting material and an electron-transporting material and dissolving a mixture into the organic solvent to form a second mixed solvent,

applying the second mixed solvent to a second substrate for manufacturing the quantum dot light-emitting element,

removing the organic solvent from the second mixed solvent to stratify the quantum dot light-emitting material and the electron-transporting material on the substrate and to form the quantum dot light-emitting layer and an electron-transporting layer.

Preferably, in the above method for manufacturing the quantum dot light-emitting element, the first substrate for manufacturing the quantum dot light-emitting element comprises a lower substrate and an anode formed on the lower substrate.

Preferably, after forming the quantum dot light-emitting layer and the hole-transporting layer, said method further comprises:

depositing the electron-transporting material on the quantum dot light-emitting layer, to form the electron-transporting layer,

forming a cathode on a surface of the electron-transporting layer,

preparing an upper substrate and connecting the upper substrate and the cathode.

Preferably, the second substrate for manufacturing the quantum dot light-emitting element comprises an upper substrate and a cathode formed on the upper substrate.

Preferably, after forming the quantum dot light-emitting layer and the electron-transporting layer, said method further comprises

depositing the hole-transporting material on a surface of the quantum dot light-emitting layer to form the hole-transporting layer,

forming an anode on the surface of the hole-transporting layer, and

preparing a lower substrate and connecting the lower substrate and the anode.

Preferably, in the above method for manufacturing the quantum dot light-emitting element, a driver circuit connected with the anode is formed on the lower substrate and a light filtering layer is formed on the upper substrate.

Preferably, in the above method for manufacturing the quantum dot light-emitting element, the organic solvent in the first mixed solvent or the organic solvent in the second mixed solvent is removed by heating.

In another aspect, the present invention also provides a display device using quantum dot, which comprises a quantum dot light-emitting element manufactured by the above method for manufacturing the quantum dot light-emitting element.

Preferably, the above display device using quantum dot further comprises:

a driver circuit, formed on the lower substrate, and

a light filtering layer, formed on the upper substrate and connected with the cathode.

Preferably, the above display device using quantum dot further comprises:

a driver circuit and a black matrix,

wherein the driver circuit and the black matrix are formed on the lower substrate, and the lower substrate is divided into a plurality of pixel corresponding areas by the black matrix, and each of the pixel corresponding areas comprises three sub-areas,

wherein the anode is formed on each of the sub-areas and is connected with the driver circuit, and in each of the sub-areas, the hole-transporting layer, the quantum dot light-emitting layer and the electron-transporting layer are successively formed from the anode up, and the quantum dot light-emitting layers located in different the sub-areas can emit lights in different colors, and the cathode is formed on the whole electron-transporting layer, and the substrate is provided to be connected with the cathode.

At least one of the above technical schemes of the specific embodiments of the present invention has the following advantages:

By using difference between particle sizes of the quantum dot light-emitting material of the quantum dot light-emitting layer and the hole-transporting material of the adjacent hole-transporting layer or the electron-transporting material of the adjacent electron-transporting layer, when the quantum dot light-emitting material for forming the quantum dot light-emitting layer is mixed with the hole-transporting material for forming the hole-transporting layer or the electron-transporting material for forming the electron-transporting layer and the mixture is dissolved in the organic solvent, during the process of removing the organic solvent, the above materials having different particle sizes are deposited by layers, so as to form the quantum dot light-emitting layer and the hole-transporting layer or form the quantum dot light-emitting layer and the electron-transporting layer. Therefore, the quantum dot light-emitting layer and the hole-transporting layer (or the quantum dot light-emitting layer and the electron-transporting layer) are prepared through a one-step process without layer-by-layer preparation, so that the manufacturing procedure of the quantum dot light-emitting element is simplified and the manufacturing cost of the quantum dot light-emitting element is further reduced. At the same time, this can solve the dissolution problem of components of the hole-transporting layer in the solvent for forming the quantum dot light-emitting layer in the current solution process.

### BRIEF DESCRIPTION OF THE DRAWINGS

FIG. 1 is a structure view showing a general structure of a quantum dot light-emitting element according to the prior art,

FIG. 2 is a structure view showing a part of quantum dot light-emitting element manufactured by the method for manufacturing the quantum dot light-emitting element in the first embodiment of the present invention,

FIG. 3 is a flow chart showing the method for manufacturing the quantum dot light-emitting element in the first embodiment of the present invention,

FIG. 4 is a structure view showing a part of quantum dot light-emitting element manufactured by a method for manufacturing the quantum dot light-emitting element in the second embodiment of the present invention,

FIG. 5 is a flow chart showing the method for manufacturing the quantum dot light-emitting element in the second embodiment of the present invention,

FIG. 6 is a Schematic diagram showing forming a quantum dot light-emitting layer and a hole-transporting layer (or an electron-transporting layer) through a one-step process,

FIG. 7 is a structure view showing the display device using quantum dot in the first embodiment of the present invention,

FIG. 8 is a structure view showing a part of the display device using quantum dot manufactured by the method for manufacturing the quantum dot light-emitting element in the first embodiment of the present invention,

FIG. 9 is a structure view showing a part of the display device using quantum dot manufactured by the method for manufacturing the quantum dot light-emitting element in the second embodiment of the present invention,

FIG. 10 is a structure view showing the display device using quantum dot in the second embodiment of the present invention.

### DETAILED DESCRIPTION

The structure and the principle of the present invention are described in detail below in combination with the appended drawings. The described embodiments are only used for explaining and illustrating the protection scope of the present invention, and are not used to limit the protection scope of the present invention.

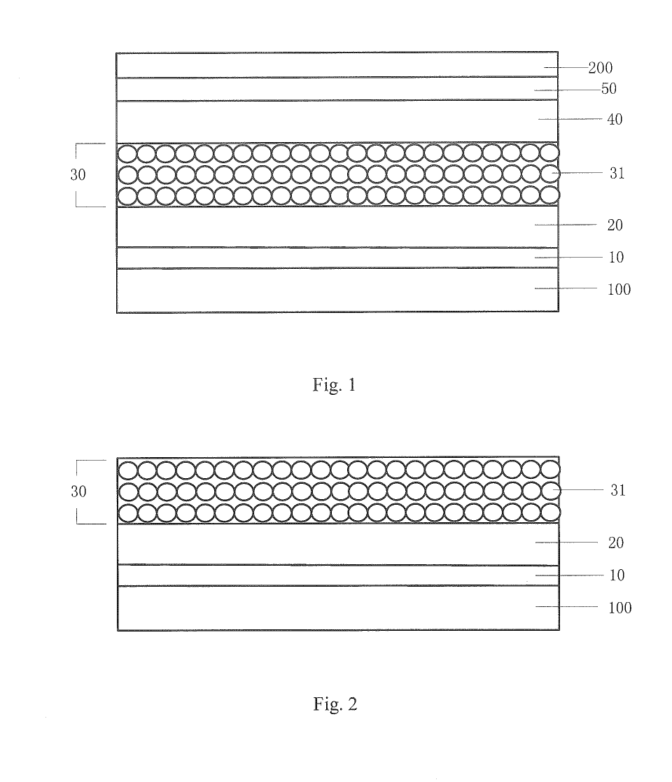

In combination with FIG. 1 which is a structure view showing a general structure of a quantum dot light-emitting element according to the prior art, a method for manufacturing a quantum dot light-emitting element described by a specific embodiment of the present invention makes use of difference between particle sizes of the quantum dot light-emitting material of the quantum dot light-emitting layer and the hole-transporting material of the adjacent hole-transporting layer or the electron-transporting material of the adjacent electron-transporting layer, when the quantum dot light-emitting material for forming the quantum dot light-emitting layer is mixed with the hole-transporting material for forming the hole-transporting layer or the electron-transporting material for forming the electron-transporting layer and the mixture is dissolved in the organic solvent, during the process of removing the organic solvent, the above materials having different particle sizes are deposited by layers, so as to form the quantum dot light-emitting layer and the hole-transporting layer or form the quantum dot light-emitting layer and the electron-transporting layer.

Therefore, the method for manufacturing the quantum dot light-emitting element described by the specific embodiment of the present invention comprises:

mixing a quantum dot light-emitting material for forming the quantum dot light-emitting layer and a hole-transporting material for forming the hole-transporting layer, and dissolving a mixture into an organic solvent to form a first mixed solvent,

applying the first mixed solvent to a substrate for manufacturing the quantum dot light-emitting element,

removing the organic solvent from the first mixed solvent applied to the substrate for manufacturing a quantum dot light-emitting element to stratify the quantum dot light-emitting material and the hole-transporting material on the substrate for manufacturing a quantum dot light-emitting element to form a quantum dot light-emitting layer, and a hole-transporting layer,

or

mixing the quantum dot light-emitting material for forming the quantum dot light-emitting layer and an electron-transporting material for forming the electron-transporting layer and dissolving a mixture into the organic solvent to form a second mixed solvent,

applying the second mixed solvent to the substrate for manufacturing the quantum dot light-emitting element,

removing the organic solvent from the second mixed solvent to stratify the quantum dot light-emitting material and the electron-transporting material on the substrate to form the quantum dot light-emitting layer and the electron-transporting layer.

By using the above method, the quantum dot light-emitting layer and the hole-transporting layer (or the quantum dot light-emitting layer and the electron-transporting layer) can be prepared through a one-step process without layer-by-layer preparation, so that the manufacturing procedure of the quantum dot light-emitting element is simplified and manufacturing cost of the quantum dot light-emitting element can further be reduced.

Additionally, the first mixed solvent and the second mixed solvent can be formed on the substrate by usual coating processes such as spin coating, inkjet, slot coating or the like. Comparing with a traditional way of manufacturing the quantum dot light-emitting layer by using a vacuum evaporation process, the purpose of simplifying the manufacturing process of the quantum dot light-emitting element, and further reducing the manufacturing cost of the quantum dot light-emitting element can also be achieved.

Phase separation is mainly influenced by the particle size and a chemical characteristic of the two materials. A size of a quantum dot light-emitting nucleus of the quantum dot light-emitting material is large, for example, the quantum dot light-emitting layer which emits a white light is formed by mixing in proportion a red quantum dot, a green quantum dot and a blue quantum dot having respectively the light-emitting nucleus sizes of 5.0˜5.5 nm, 3.0˜3.5 nm and 2.0˜2.5 nm, so the size of the quantum dot light-emitting nucleus is about 3˜10 nm and a surface of the quantum dot is coated with a alkane. While the hole-transporting material, such as a tetraphenylbenzidine compound, N, N′-diphenyl-N, N′-di (3-tolyl)-1, 1′-biphenyl-4, 4′-diamine (which is called TPD for short), 4,4′-N, N′-dicarbazole-biphenyl (which is called CBP for short), N,N′-diphenyl-N,N′-di (1-naphthyl-1, 1′-biphenylyl-4, 4′-diamine) (which is called a-NPD for short), 4,4′,4″-tri (N-carbazolyl)-triphenylamine (which is called TCA for short), is aromatic having a small molecule size of 1 nm, so after the two materials are mixed and dissolved in the organic solvent, during the process of removing the organic solvent, the quantum dot light-emitting material coated with a alkane may be separated from the hole-transporting material as aromatic compounds. When the surface of the substrate applied with the mixed solvent is placed upwards, the quantum dot light-emitting material moves toward an upper portion of the organic solvent to form the quantum dot light-emitting layer covering the hole-transporting layer, and the hole-transporting layer is formed below the quantum dot light-emitting layer. The preparation of the hole-transporting layer and the quantum dot light-emitting layer is implemented through the one-step process.

The electron-transporting material for forming the electron-transporting layer may be an organic material such as TPBI (1,3,5-tri(N-Phenylbenzimidazole-2-yl) benzol), TAZ (3-(4-biphenyl)-4-phenyl-5-tert-butylphenyl-1,2,4-triazole), AlQ3 (tri (8-hydroxyquinoline) Al) and the like. Based on the same principle as the above, the preparation of the electron-transporting layer and quantum dot light-emitting layer may also be implemented through the one-step process.

In the method for manufacturing the quantum dot light-emitting element described in the embodiment of the present invention, the “substrate for manufacturing a quantum dot light-emitting element” is a substrate subjected to the processes before forming the quantum dot light-emitting layer and the hole-transporting layer or forming the quantum dot light-emitting layer and the electron-transporting layer in the processes for manufacturing the quantum dot light-emitting element. Therefore, it is not limited to only include a transparent glass substrate, but may also include the transparent glass substrate on which an anode, a driver circuit and the like is formed.

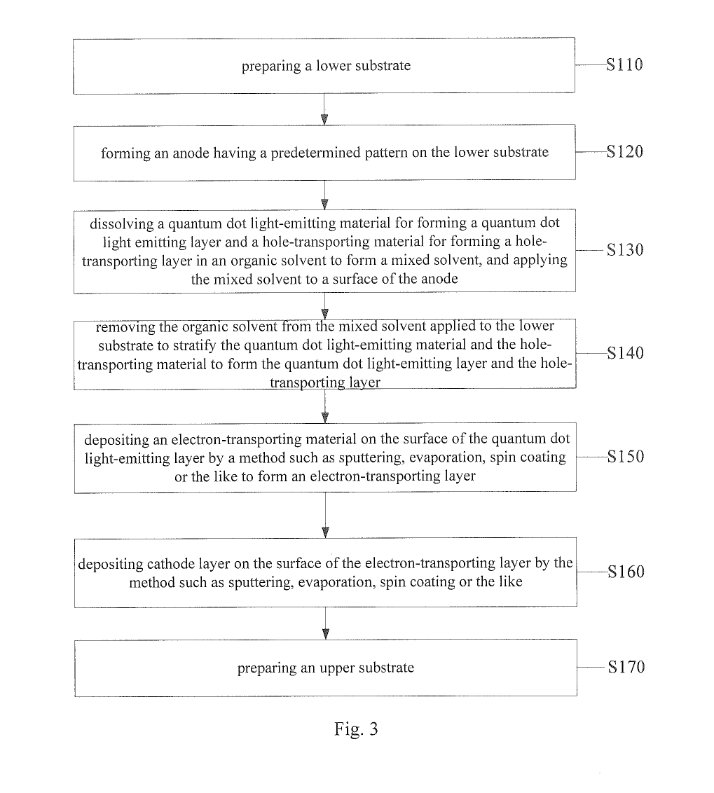

The method in the first embodiment of the present invention will be described in detail below in combination with FIGS. 1, 2, 3 and 6. When a quantum dot light-emitting layer 30 and a hole-transporting layer 20 are prepared through the one-step process, the method for manufacturing the quantum dot light-emitting element specifically comprises the following steps.

S110, preparing a lower substrate 100, wherein the lower substrate 100 generally comprises a transparent glass substrate,

S120, forming an anode 10 having a predetermined pattern on the lower substrate 100 to form the substrate for manufacturing a quantum dot light-emitting element, wherein the anode 10 can be formed on the lower substrate 100 by using the method such as sputtering, evaporation, spin coating or the like. A person skilled in this art should know the above process, and the details will not be described here.

S130, dissolving a quantum dot light-emitting material for forming the quantum dot light-emitting layer and a hole-transporting material for forming the hole-transporting layer into an organic solvent to form a mixed solvent, and applying the mixed solvent to a surface of the anode 10, wherein applying may be performed by such as spin coating, inkjet, slot coating or the like. The above way for applying is well known by a person skilled in the art, and the details will not be described here.

S140, removing the organic solvent from the mixed solvent applied to the lower substrate 100, wherein the organic solvent may be toluene, and the organic solvent may be removed by heating. Along with the process of heating the lower substrate 100, the organic solvent evaporates. Because the particle size of the quantum dot light-emitting material in the mixed solvent applied to the lower substrate 100 is larger than that of the hole-transporting material, the quantum dot material moves upwards and the quantum dot light-emitting layer 30 is formed on the hole-transporting layer 20. The principle of this process is shown in FIG. 6.

Optimally, a temperature for heating the organic solvent is 70° C.˜90° C.

Apart from heating to remove the organic solvent from the mixed solvent, natural volatilization at the environmental temperature may also be adopted to prepare and stratify the quantum dot light-emitting layer and the hole-transporting layer.

S150, depositing the electron-transporting material on the surface of the quantum dot light-emitting layer 30 by using the method such as sputtering, evaporation, spin coating or the like to form the electron-transporting layer 40,

S160, depositing the cathode 50 on the surface of the electron-transporting layer 40 by using the method such as sputtering, evaporation, spin coating or the like,

S170, manufacturing the upper substrate 200, which generally comprises the transparent glass substrate.

By the above steps S110 to S170, the quantum dot light-emitting element shown in FIG. 1 has been prepared.

The method in the second embodiment of the present invention and the process for preparing the quantum dot light-emitting element will be described in detail below in combination with FIGS. 1, 4, 5 and 6, wherein the quantum dot light-emitting layer and the electron-transporting layer are prepared through the one-step process.

S210, manufacturing an upper substrate 200, wherein the upper substrate 200 generally comprises the transparent glass substrate,

S220, forming an cathode 50 on the upper substrate 200 by the method such as sputtering, evaporation, spin coating or the like,

S230, dissolving the quantum dot light-emitting material for forming the quantum dot light-emitting layer and the electron-transporting material for forming the electron-transporting material into the organic solvent to form the mixed solvent, and applying the mixed solvent to the surface of the cathode 50 by the method such as span coating, inkjet, slot coating or the like,

S240, removing the organic solvent from the mixed solvent applied to the upper substrate 200, wherein the organic solvent may be removed by heating, and the organic solvent evaporates along with heating the upper substrate 200, because the particle size of the quantum dot light-emitting material in the mixed solvent applied to the upper substrate 200 is larger than that of the electron-transporting material for forming the electron-transporting layer, the quantum dot light-emitting material moves upwards and the quantum dot light-emitting layer 30 is formed on the electron-transporting layer 40, as shown in FIG. 6,

S250, depositing the hole-transporting material on the surface of the quantum dot light-emitting layer 30 by the method such as sputtering, evaporation, spin coating or the like,

S260, depositing an anode layer 10 on the surface of the hole-transporting layer 20 by the method such as sputtering, evaporation, spin coating or the like,

S270, manufacturing a lower substrate 100, wherein the lower substrate 200 generally comprises the transparent glass substrate.

By using the above steps S210 to S270, the quantum dot light-emitting element having the structure shown in FIG. 1 has been prepared.

The “quantum dot light-emitting element” mentioned in the above content of the present invention may be a quantum dot light-emitting diode or may be a display device using quantum dot. An element can be prepared by the method described by the embodiments of the present invention as long as the element is an element using quantum dot light-emitting material.

When the quantum dot light-emitting element is a display device using quantum dot, in order to implement color image display of the display device, a driver circuit for driving the anode 20 is formed on the lower substrate 100 having the structure shown in FIG. 1 and a light filtering layer is formed on the upper substrate 200.

In another aspect, the embodiment of the present invention also provides a display device using quantum dot manufactured by the method for manufacturing the quantum dot light-emitting element. The display device using quantum dot comprises the quantum dot light-emitting element having the structure shown in FIG. 1, which comprises the lower substrate, the anode, the quantum dot light-emitting layer, the hole-transporting layer, the electron-transporting, the cathode and the upper substrate.

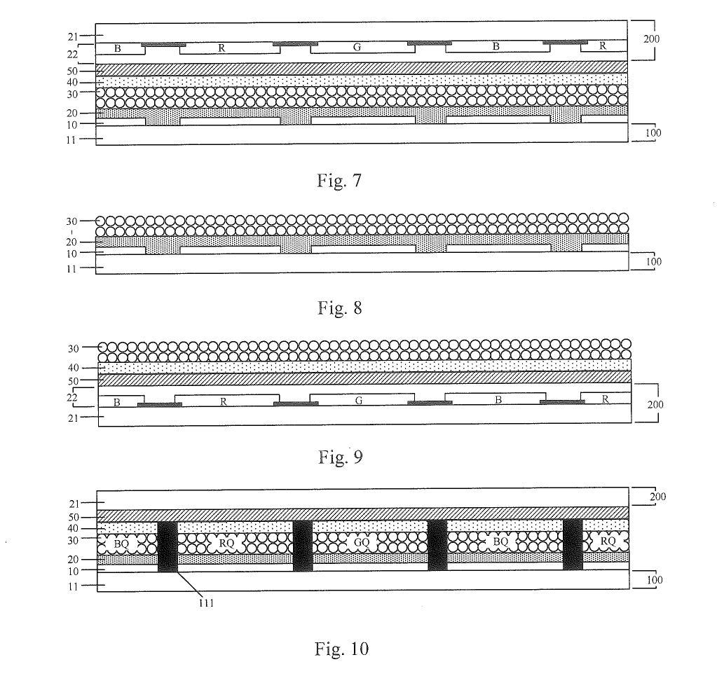

FIG. 7 is a structure view showing the first embodiment of the display device using quantum dot described in the present invention.

As shown in FIG. 7, in the first embodiment, the display device using quantum dot comprises the lower substrate 100, the upper substrate 200, and a quantum dot light-emitting portion provided between the upper substrate 200 and the lower substrate 100, wherein,

the lower substrate 100 comprises a transparent glass substrate 11, wherein the driver circuit is formed on the transparent glass substrate 11,

the quantum dot light-emitting portion comprises, from a surface of the transparent glass substrate 11 to top in turn, the anode 10, the hole-transporting layer 20, the quantum dot light-emitting layer 30, the electron-transporting layer 40, and the cathode 50,

The lower substrate 200 comprises a transparent glass substrate 21 and a light filtering layer 22, and the light filtering layer 22 comprises a black matrix and a color film forming a plurality of pixels. Wherein, the structure of the light-filtering layer 22 is the same as that of the light filtering layer in a general liquid crystal display.

The display device using quantum dot shown in FIG. 7 is used, and the anode 10 corresponding to each of pixels is separately connected to a thin film transistor (TFT) having an independent driving function (not shown in the figure). Therefore, different voltages are applied to each of pixels according to requirements for an image displayed by a display device, and there exist different voltages and different currents between the anode 10 and the cathode 50. Therefore, each of pixels can emits a light having a different brightness according to a color set by the image, and the lights are mixed to form the image to be displayed after the lights are filtered by the light filtering layer 22. when the display device using quantum dot having the structure shown in FIG. 7 is manufactured by the method for manufacturing the quantum dot light-emitting element in the present invention, according to the principle of the method of the present invention, the quantum dot light-emitting layer 30 and the hole-transporting layer 20, or the quantum dot light-emitting layer 30 and the electron-transporting layer 40, can be prepared through the one-step process.

When the quantum dot light-emitting layer 30 and the hole-transporting layer 20 are prepared through the one-step process, as shown in the steps S110 to S170 and FIG. 8, the method for manufacturing the display device using quantum dot in the first embodiment of the present invention comprises:

preparing the lower substrate 100, which comprises the driving circuit formed on the transparent glass substrate 11,

forming the patterned anode 10 on the lower substrate 100 to form the substrate for manufacturing a quantum dot light-emitting element,

mixing and dissolving the quantum dot light-emitting material for forming the quantum dot light-emitting layer 30 and the hole-transporting material for forming the hole-transporting layer 20 into the organic solvent and applying the mixed solvent to the surface of the anode 10,

removing the organic solvent from the mixed solvent applied to the lower substrate 100, wherein the organic solvent may be removed by heating, along with the process of heating of the lower substrate 100, the quantum dot light-emitting layer 30 is formed on the hole-transporting layer 20,

depositing the election-transporting material on the surface of the quantum dot light-emitting layer 30 by the method such as sputtering, evaporation, spin coating or the like,

depositing the cathode 50 layer on the surface of the electron-transporting layer 40 by the method such as sputtering, evaporation, spin coating or the like,

preparing the upper substrate 200, which comprises a step of forming the light filtering layer 22 on the transparent glass substrate 21.

When the quantum dot light-emitting layer 30 and the electron-transporting layer 40 are prepared through the one-step process, as shown in the steps S210 to S270 and FIG. 9, the method for manufacturing the display device using quantum dot in the first embodiment of the present invention comprises:

preparing the upper substrate 200, which include a step of forming the light filtering layer 22 on the transparent glass substrate 21,

forming the cathode 50 on the upper substrate 200 by the method such as sputtering, evaporation, spin coating or the like,

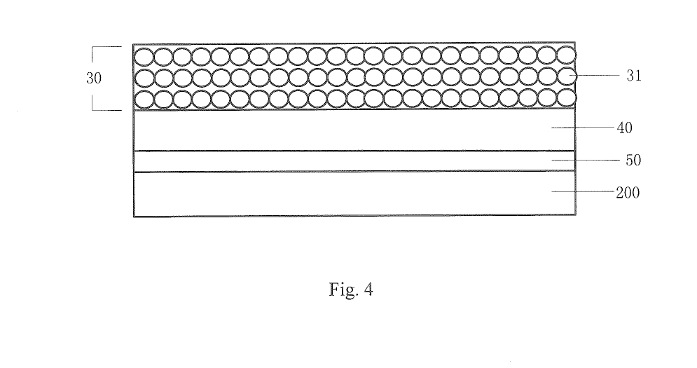

dissolving the quantum dot light-emitting material for forming the quantum dot light-emitting layer and the electron-transporting material for forming the electron-transporting layer into the organic material to form the mixed solvent shown in FIG. 4, and applying the mixed solvent to the surface of the cathode 50 by the method such as spin coating, ink jetting, slot coating or the like,

removing the organic solvent from the mixed solvent applied to the upper substrate 200, wherein the organic solvent may be removed by heating, along with the process of heating the upper substrate 200, the quantum dot light-emitting layer 30 is formed on the electron-transporting layer 40,

depositing the hole-transporting material on the surface of the quantum dot light-emitting layer 30 by the method such as sputtering, evaporation, spin coating or the like, to form the hole-transporting layer 20,

depositing the anode layer 10 on the surface of the hole-transporting layer 20 by the method such as sputtering, evaporation, spin coating or the like,

preparing the lower substrate 100, which comprises a step of forming the driver circuit on the transparent glass substrate 11.

A person skilled in this art should know the specific method for forming the driver circuit on the lower substrate 100 and forming the light filtering layer on the upper substrate 200. This part is not an emphasis mainly studied by the present invention, and the details will not be described here.

Additionally, the second embodiment of the display device using quantum dot is also provided by the present invention, as shown in FIG. 10, which comprises the lower substrate 100, the upper substrate 200 and the quantum dot light-emitting element provided between the lower substrate 100 and the upper substrate 200.

The lower substrate 100 comprises the transparent glass substrate 11. The driver circuit and a black matrix 111 are formed on the transparent glass substrate 11, the lower substrate is divided by the black matrix 111 into a plurality of pixel corresponding areas, and each pixel corresponding area comprises three sub-areas.

The anode 10 is formed on each of the sub-areas, and the anode 10 is connected to the driver circuit. In each of the sub-areas, the hole-transporting layer 20, the quantum dot light-emitting layer 30 and the electron-transporting layer 40 are formed from the anode 10 to top, and the quantum dot light-emitting layers 30 in different sub-areas can emit lights in different colors.

The cathode 50 is formed on the whole electron-transporting layer 40.

The upper substrate 200 comprising the transparent glass substrate 21 is provided to be connected with the cathode 50.

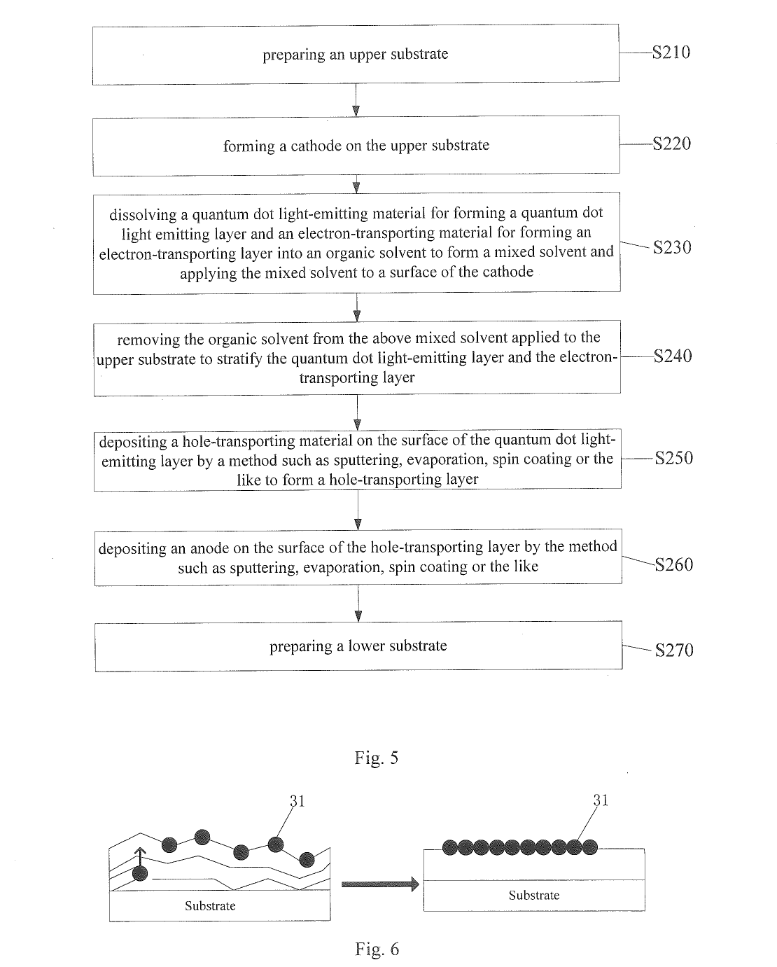

The display device using quantum dot having the structure of the second embodiment as shown in FIG. 8 make use of a property of the quantum dot (i.e. the quantum dot can emit the lights in different colors when the particle sizes of the quantum dot light-emitting nucleuses are different) to make the quantum dot light-emitting layers 30 in different sub-areas emit the lights in different colors, preferably a red light, a green light and a blue light, by providing the quantum dots having different particle sizes in three different sub-areas. Therefore, an image of the three primary colors R, G, B displayed by the display device can be implemented without the light filtering layer 22 as shown in FIG. 5.

When the display device using quantum dot having the structure as shown in FIG. 10 is manufactured by the method for manufacturing the quantum dot light-emitting element in the present invention, the quantum dot light-emitting layer 30, the hole-transporting layer 20 and the electron-transporting layer 40 are respectively divided into a plurality of areas by the black matrix 111. Thus, the above layers depend on the black matrix 111. The above may be prepared by the following way: forming the matrix 111 on the lower substrate 100 to form the substrate for manufacturing the quantum dot light-emitting element, preparing the quantum dot light-emitting layer 30 and the hole-transporting layer 20 on the substrate for manufacturing the quantum dot light-emitting element through the one-step process, and forming the electron-transporting layer 40, which specifically comprises the following steps:

preparing the lower substrate 100 of the display device using quantum dot, which comprises the step of forming the driver circuit and the black matrix 111 on the lower substrate 100 in turn, wherein the lower substrate 100 is divided into a plurality of pixel corresponding areas by the black matrix 111, and each of pixel corresponding areas comprises three sub-areas,

forming the anode 10 on each of the sub-areas of the lower substrate 100 to form the substrate for manufacturing the quantum dot light-emitting element,

masking two of the three sub-areas and applying he mixed solvent including the quantum dot light-emitting material and the hole-transporting material to the remaining sub-area, wherein the quantum dot light-emitting material on the remaining sub-area emits a red light, and by using the same step, applying the mixed organic including the quantum dot light-emitting material and the hole-transporting material to the two sub-areas except that the quantum dot light-emitting materials in the organic solvent are different and the quantum dot light-emitting materials emit a green light and a blue light separately,

heating the lower substrate applied with the mixed solvent, evaporating the organic solvent from the mixed solvent, and forming the quantum dot light-emitting layer 30 in each of sub-areas on the hole-transporting layer 20,

depositing the electron-transporting material on the surface of the quantum dot light-emitting layer 30 in each of the sub-area to form the electron-transporting layer 40,

forming the cathode 50 on the surface of the whole electron-transporting layer 40, and

preparing the upper substrate 200 of the display device using quantum dot and connecting the upper substrate 200 with the cathode 50.

Therefore, the display device using quantum dot having the structure as shown in FIG. 10 can also be prepared by the method for manufacturing the quantum dot light-emitting element of the present invention.

The method for manufacturing the quantum dot light-emitting element and the display device using quantum dot manufactured by the method for manufacturing the quantum dot light-emitting element in the embodiment of the present invention prepare the hole-transporting layer (or the electron-transporting layer) and the quantum dot light-emitting layer through the one-step process by dissolving the hole-transporting material and the quantum dot light-emitting material, or the quantum dot light-emitting material and the electron-transporting material for forming the electron-transporting layer into the same solvent by common coating process such as spin coating, inkjet, spin coating or the like. Comparing with the traditional vacuum evaporation and the traditional layer-by-layer preparation, the present invention not only simplifies the preparation procedure and reduces the cost, but also can prepare the compact and uniform quantum dot light-emitting layer and improves an interface between the quantum dot light-emitting layer and the hole-transporting layer or the electron-transporting layer. Therefore, the display device using quantum dot of the present invention has advantages such as a lower cost, a high light-emitting efficiency and a good display quality such as a high color gamut, a high brightness and the like.

All those described above are preferred embodiments of the present invention. It should be point out that, several improvements and modifications can be made by a person having ordinary skill in this art without departing from the protection scope of the present invention. All the improvements and modifications should also be regarded as the protection scope of the present invention.

1. A method for manufacturing a quantum dot light-emitting element, comprising:
mixing a quantum dot light-emitting material and a hole-transporting material and dissolving a mixture into an organic solvent to form a first mixed solvent,
applying the first mixed solvent to a first substrate for manufacturing the quantum dot light-emitting element, and
removing the organic solvent from the first mixed solvent to stratify the quantum dot light-emitting material and the hole-transporting material on the substrate and to form a quantum dot light-emitting layer and a hole-transporting layer,
or
mixing the quantum dot light-emitting material and an electron-transporting material and dissolving a mixture into the organic solvent to form a second mixed solvent,
applying the second mixed solvent to a second substrate for manufacturing the quantum dot light-emitting element, and
removing the organic solvent from the second mixed solvent to stratify the quantum dot light-emitting material and the electron-transporting material on the substrate and to form the quantum dot light-emitting layer and an electron-transporting layer.

2. The method for manufacturing the quantum dot light-emitting element according to claim 1, wherein the first substrate for manufacturing the quantum dot light-emitting element comprises a lower substrate and an anode formed on the lower substrate.

3. The method for manufacturing the quantum dot light-emitting element according to claim 2, wherein after forming the quantum dot light-emitting layer and the hole-transporting layer, said method further comprises:
depositing the electron-transporting material on the quantum dot light-emitting layer to form the electron-transporting layer,
forming a cathode on a surface of the electron-transporting layer, and
preparing an upper substrate and connecting the upper substrate and the cathode.

4. The method for manufacturing the quantum dot light-emitting element according to claim 1, wherein the second substrate for manufacturing the quantum dot light-emitting element comprises an upper substrate and a cathode formed on the upper substrate.

5. The method for manufacturing the quantum dot light-emitting element according to claim 4, wherein after forming the quantum dot light-emitting layer and the electron-transporting layer, said method further comprises
depositing the hole-transporting material on a surface of the quantum dot light-emitting layer to form the hole-transporting layer,
forming an anode on the surface of the hole-transporting layer, and
preparing a lower substrate and connecting the lower substrate and the anode.

6. The method for manufacturing the quantum dot light-emitting element according to claim 3, wherein a driver circuit connected with the anode is formed on the lower substrate and a light filtering layer is formed on the upper substrate.

7. The method for manufacturing the quantum dot light-emitting element according to claim 1, wherein the organic solvent in the first mixed solvent or the organic solvent in the second mixed solvent is removed by heating.

8. A display device using quantum dot comprising a quantum dot light-emitting element manufactured by a method for manufacturing the quantum dot light-emitting element comprising:
mixing a quantum dot light-emitting material and a hole-transporting material and dissolving a mixture into an organic solvent to form a first mixed solvent,
applying the first mixed solvent to a first substrate for manufacturing the quantum dot light-emitting element, and
removing the organic solvent from the first mixed solvent to stratify the quantum dot light-emitting material and the hole-transporting material on the substrate and to form a quantum dot light-emitting layer and a hole-transporting layer,
or
mixing the quantum dot light-emitting material and an electron-transporting material and dissolving a mixture into the organic solvent to form a second mixed solvent,
applying the second mixed solvent to a second substrate for manufacturing the quantum dot light-emitting element, and
removing the organic solvent from the second mixed solvent to stratify the quantum dot light-emitting material and the electron-transporting material on the substrate and to form the quantum dot light-emitting layer and an electron-transporting layer

9. The display device using quantum dot according to claim 8, further comprising:
a driver circuit, formed on the lower substrate, and
a light filtering layer, formed on the upper substrate and connected with the cathode.

10. The display device using quantum dot according to claim 8, further comprising:
a driver circuit and a black matrix,
wherein the driver circuit and the black matrix are formed on the lower substrate, and the lower substrate is divided into a plurality of pixel corresponding areas by the black matrix, and each of the pixel corresponding areas comprises three sub-areas,
wherein the anode is formed on each of the sub-areas and is connected with the driver circuit, and in each of the sub-areas, the hole-transporting layer, the quantum dot light-emitting layer and the electron-transporting layer are successively formed from the anode up, and the quantum dot light-emitting layers located in different the sub-areas can emit lights in different colors, and the cathode is formed on the whole electron-transporting layer, and the substrate is provided to be connected with the cathode.

11. The method for manufacturing the quantum dot light-emitting element according to claim 5, wherein a driver circuit connected with the anode is formed on the lower substrate and a light filtering layer is formed on the upper substrate.

12. The display device using quantum dot according to claim 8, wherein the first substrate for manufacturing the quantum dot light-emitting element comprises a lower substrate and an anode formed on the lower substrate.

13. The display device using quantum dot according to claim 12, wherein after forming the quantum dot light-emitting layer and the hole-transporting layer, said method further comprises:
depositing the electron-transporting material on the quantum dot light-emitting layer to form the electron-transporting layer,
forming a cathode on a surface of the electron-transporting layer, and
preparing an upper substrate and connecting the upper substrate and the cathode.

14. The display device using quantum dot according to claim 8, wherein the second substrate for manufacturing the quantum dot light-emitting element comprises an upper substrate and a cathode formed on the upper substrate.

15. The display device using quantum dot according to claim 14, wherein after forming the quantum dot light-emitting layer and the electron-transporting layer, said method further comprises
depositing the hole-transporting material on a surface of the quantum dot light-emitting layer to form the hole-transporting layer,
forming an anode on the surface of the hole-transporting layer, and
preparing a lower substrate and connecting the lower substrate and the anode.

16. The display device using quantum dot according to claim 13, wherein a driver circuit connected with the anode is formed on the lower substrate and a light filtering layer is formed on the upper substrate.

17. The display device using quantum dot according to claim 15, wherein a driver circuit connected with the anode is formed on the lower substrate and a light filtering layer is formed on the upper substrate.

18. The display device using quantum dot according to claim 8, wherein the organic solvent in the first mixed solvent or the organic solvent in the second mixed solvent is removed by heating.
